(19) United States
(12) Patent Application Publication
(10) Pub. No.: US 2024/0145434 A1
(43) Pub. Date: May 2, 2024

(54) MULTI PROGRAMABLE-DIE MODULE

(71) Applicant: Intel Corporation, Santa Clara, CA (US)

(72) Inventors: Mahesh KUMASHIKAR, Bangalore (IN); MD Altaf HOSSAIN, Portland, OR (US); Ankireddy NALAMALPU, Portland, OR (US)

(21) Appl. No.: 18/210,847

(22) Filed: Jun. 16, 2023

(51) Int. Cl. H01L 25/065; H01L 23/498; H01L 23/538

(52) U.S. Cl. CPC H01L 25/0655; H01L 23/49833; H01L 23/5384; H01L 23/5386; H01L 24/16

(57) ABSTRACT

Die configuration types are provided that may be used together with other instances of the design to create multi die modules.

### TECHNICAL FIELD

This disclosure relates generally to multi-chip packages and in particular, to improved techniques for reducing a number of required die-design types for a multi-chip package implementation.

### BRIEF DESCRIPTION OF THE DRAWINGS

The invention may best be understood by referring to the following description and accompanying drawings that are used to illustrate embodiments of the invention. In the drawings:

FIGS. 1A through 1C are diagrams showing a conventional programmable die and multi-die module.

FIGS. 2A through 2C are diagrams showing a programmable die and multi-die module configurations in accordance with some embodiments.

FIG. 3 is a top view diagram of a programmable die layout in accordance with some embodiments.

FIG. 4 is a top view diagram of a programmable die layout in accordance with some other embodiments.

FIG. 5 is a side view diagram showing a multi-chip programmable die configuration in accordance with some embodiments.

FIG. 6 shows a data processing system with one or more programmable device modules in accordance with some embodiments.

### DETAILED DESCRIPTION

In some embodiments, programmable devices such as FPGAs may be used to create multi-chip computing systems, for example, to prototype system designs prior to committing with fixed CPUs, GPUs, ASICS, and the like. Usually, several different programable die designs have been needed to implement the system. Unfortunately, this can cost excessive money and time in creating and verifying the different masks and manufacture processes needed for multiple different die designs. Accordingly, in some embodiments, new die configuration types are provided that may be used together with other instances of the design to create multi die modules requiring just the single die type. For example, in some embodiments, a module may use a bridge with through silicon via (TSV) capabilities or an interposer to facilitate single die tape-in instead of requiring multiple, unique die tape-ins. A reduced number of required die types may result in a reduced number of required tape-ins, which can result in mask cost savings, as well as improvements in design turn-around time. In addition, test program development may be simplified, and product costs may be improved as volume is served by the reduced number of die types and wafers, resulting in improved yield.

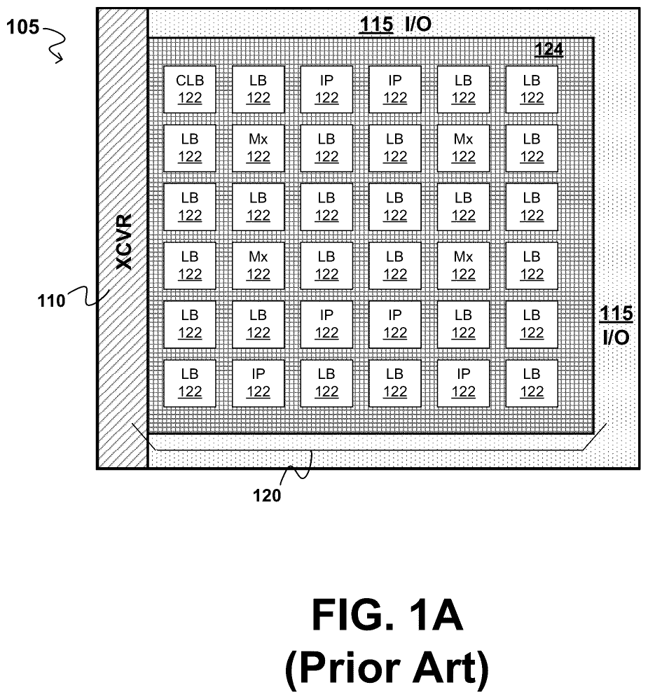

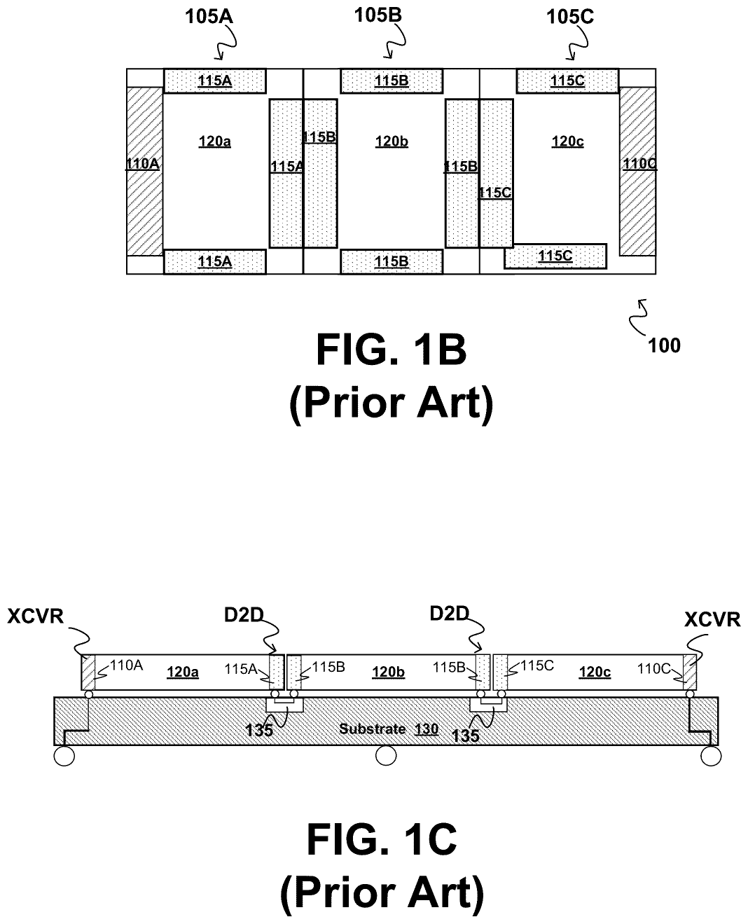

FIGS. 1A through 1C show a conventional monolithic FPGA (field programmable gate array) integrated circuit (IC) device 105. With reference to FIG. 1A, an FPGA may generally be divided into two basic regions, a peripheral outer region (also referred to as “shoreline” and an inner processing and communications region 120. In this depiction, the peripheral region has a transceiver portion (XCVR) 110 and general input/output (I/O) region 115. External communication with the FPGA 105 typically occurs through the transceiver(s) 110 and/or through the general IO blocks 115, although it may be more convenient to use high-speed differential XCVR (transceiver) interface 110 to communicate with external devices for bandwidth intensive and/or lengthy communications. Standard protocols including but not limited to Ethernet, PCI Express (PCIe), USB, etc. may be used for such high-speed interfaces 110. Moreover, they could be implemented with TMD (transition minimized differential) signaling, (e.g., for HDMI), MGT (multi-gigabit transceiver) signaling (e.g., PCIe, Display Port) and/or other suitable physical signaling schemes.

The general IO blocks 115 may be used for die-to-die (D2D) connectivity, e.g., employing PAM, single-ended, differential, Serdes, and/or parallel interface implementations. In addition, they could also be used to implement external communication interfaces such as for off-chip memory (e.g., DDR, GDDR) or programming, test, or monitoring (e.g., I2C, SPI) depending on particular design objectives.

The interior processing region 120 generally includes a plurality of functional circuit blocks 122 coupled together through a programmable interconnect fabric 124. As indicated, functional blocks 122 may include a variety of different processing block types including configurable logic blocks (CLBs), intellectual property (e.g., hardened IP, HIP) blocks for performing specific functions, and memory blocks (Mx).

CLBs typically include three elements: look-up tables (LUTs), multiplexers, and flipflops. The IP blocks are typically used for performing specialized logical, mixed signal and/or analog circuits for implementing fundamental arithmetic functionality such as adders, MACs (multiply accumulate), security, DSP, GPU and CPU cores, memory and IO controllers, clock generation circuits, and the like. As technologies advance, more and more functional block options become feasible for FPGA incorporation.

With programmable logic, LUTs are the primary elements for implementing configurable logical functions. For example, they can be arranged and controlled to generate truth table operation for any desired combinational logic function. The flip flops are used for sequential logic implementation. They also may be used to efficiently incorporate adders/multipliers and DSP logic, for example, inside the CLBs themselves, to reduce latency, facilitate faster computation, reduce routing, and increased throughput. The multiplexers, among other things, are used to select the data output and pathways between the LUTs and flops to configure the desired logical functionality.

The memory blocks may include a combination of volatile and non-volatile memory such as RAM (random access memory), ROM (read only memory), flash memory and the like. The memory may be used for a variety of purposes such as for storing programable logic configurations, implementing processor architecture memory (e.g., distributed and block RAM for cache functionality), buffering data, and the like.

The functional blocks 122 are coupled to each other and to the IO interfaces through programmable interconnect fabric 124. The interconnect fabric may be implemented in any suitable manner. For example, it may be formed as a routing matrix comprising programmable switches, wires, clock network elements, and the like. The routing elements provide connections between the IO blocks 110, 115 and the data processing section 120, and also between the functional blocks 122 themselves.

FIG. 1B shows a simplified top view of a conventional multi-chip programmable device system. For example, it could be used to implement a computing system prototype. FPGAs are commonly used to prototype computing systems such as servers, data-center computing blocks, high performance computers, and the like. They can be useful because they may be relatively flexible for implementing a variety of design functionality, and they are re-configurable, which makes them useful for isolating design issues and optimizing performance.

The multi-chip FPGA device of FIG. 1B has three different monolithic FPGA dies, 105A, 105B, and 105C. The left die (105A) has a transceiver block 110A on its left edge with die-to-die IO on its right edge. The upper and lower edges comprise general Io blocks 115A, which could be used for die-to-die or other IO interface functions. In contrast, the second die (105B) doesn't incorporate XCVR blocks and instead, uses its shoreline edges for general IO blocks 115B including D2D blocks on its left and right edges. Finally, the third die (105C) has an XCVR block on its right edge, a D2D block on its left edge and general IO blocks on its upper and lower shoreline edges. With conventional techniques, these individual die layouts allow for the three chips to be coupled together, as can be seen in the side view of FIG. 1C, using bridges 135, which are disposed in a multi-chip substrate 130. The D2D blocks are aligned next to each other, which allows for them to be coupled together using the bridges. Likewise, the XCVR blocks 110 are disposed on the outside edges (left edge of left die and right edge of right die), making them accessible for off-chip communications.

Unfortunately, these conventional approaches require the use of different die designs (e.g., layouts), which can dramatically increase the time and resources needed to make all of the dies. They require multiple tape-ins, resulting in significant mask cost. In addition, fixing bugs for different die types can result in additional tape-ins when trouble-shooting multiple, different designs.

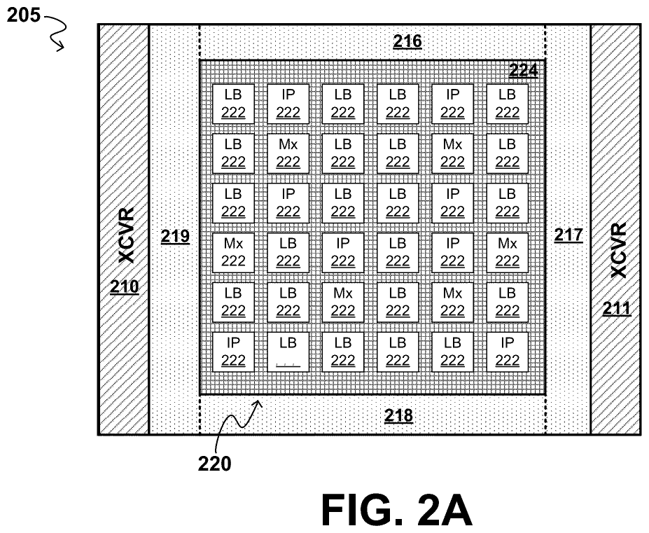

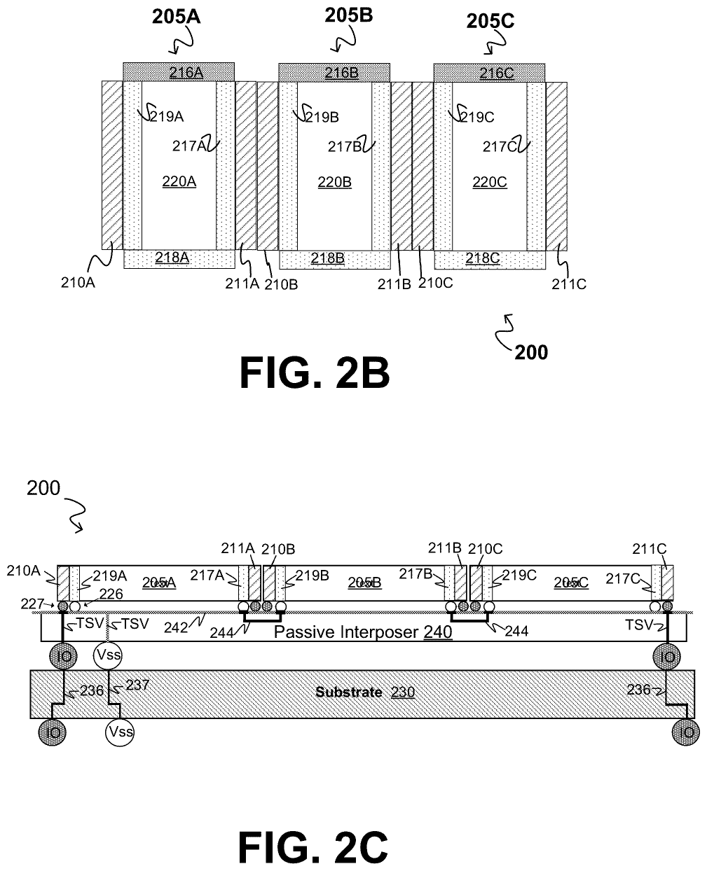

FIG. 2A is a top view of a programmable die (e.g., FPGA) 205 design having a transceiver and D2D layout in accordance with some embodiments. The design allows for multiple instances of the same die type to be used together to form a multi-chip system such as a computing system using multiple FPGAs. Die 205 has an interior processing region 220 with functional blocks 222 and a programmable fabric network 224. It also has transceiver blocks 210, 211 and IO blocks 216-219, of which, some or all may be used as D2D blocks for coupling with adjacent dies. The remaining portion(s) may not be used or may be used for other off-chip IO functionality such as DDR.

FIG. 2B is a top view of a multi-chip system 200 using three instances (205A, 205B, 205C) of a common die design 205 such as the die design of FIG. 2A in accordance with some embodiments. In this embodiment, IO blocks 217 and 219 are used for adjacent D2D connectivity. In particular, D2D block 217A is coupled to D2D block 219B, and D2D block 217B is coupled to D2D block 219C. Transceiver blocks 210A and 211C are used for off-chip communications, while “interior” transceiver blocks 211A, 210B, 211B, and 210C are unused. In some embodiments, they may be coupled to reference rails (e.g., ground) to ensure they are inert, avoiding unnecessary power losses from leakage or other causes.

It should be appreciated that any suitable technology for implementing a multi-chip package of dies (e.g., multiple FPGA dies, or even multiple CPU, GPU, or ASIC dies) including 2D, 2.5D and/or 3D methodologies may be employed. For example, wafer-level fan-out redistribution, using reconstituted wafer substrates of molding compounds as the surface for interconnections between dies may be used in 2D or 2.5D implementations. Similarly, with some methods, a separate, usually silicon-based, interconnect layer for redistribution could be used. For example, either an interposer (passive and/or active, typically formed from silicon) or die-to-die bridges (e.g., silicon bridges) embedded in an organic surface (e.g., substrate surface or interposer) could be employed.

An interposer is typically formed from a piece of silicon, large enough to accommodate the multiple chips with the chips being bonded to the interposer. Interposers typically include multiple signal lines (e.g., data lines), and because the data is being moved from silicon to silicon, the loss of power may be minimized.

Bridges, such as EMIB (Embedded Multi-Die Interconnect Bridge), developed by Intel Corp., may also be employed. EMIB is an example of a 2.5D MCP bridge interconnect technology. In some forms, EMIB may be a combination of both interposer and substrate. Rather than simply employing a large interposer, this technique may use a small slither of silicon (the bridge) embedded into the substrate. Such a bridge may include hundreds or thousands of connections to couple adjacent sides of two chips together. In this way, data between the chips may be transferred through silicon without excessive restrictions. Also, multiple bridges between two chips may be employed if more bandwidth is needed, or multiple bridges for designs using more than two chips could also be used.

Any suitable architectures for implementing the general IO blocks may be employed. For example, for D2D implementations, proprietary or standard protocols such as Advanced Interface Bus (AIB) or Universal Chiplet Interconnect Express (UCIe) may be used. Regardless, the physical layer architecture can be SerDes-based or parallel-based. A SerDes-based architecture typically includes parallel-to-serial (serial-to-parallel) data conversion, impedance matching circuitry, and in some cases, clock data recovery or clock forwarding functionality. The primary role for using a SerDes architecture may be to minimize the number of IO interconnects in simple 2D-type multi-chip packaging, e.g., as with organic substrates employing bridges, or the like, for the D2D connections.

On the other hand, a parallel based architecture typically includes many low-speed, simple IO channels in parallel, each made of a driver and a receiver with forwarding clock techniques to further simplify the architecture. It supports DDR-type signaling and for certain multi-chip designs, may be well-suited for D2D applications. For example, a parallel architecture may be well suited for minimizing power in dense 2.5D type packaging, as with, for example, the use of silicon interposers.

FIG. 2C is a side view of the multi-chip system 200 from FIG. 2B. System 200 includes a passive interposer 240 mounted atop a substrate 230 as shown. Passive interposer 240 includes a conductive “reference” layer 242, e.g., a ground plane layer, along with conductive signal lines 244. Ball contacts (e.g., micro bumps) conductively couple the interior unused transceiver blocks (211A, 210B, 211B, 210C) to a reference layer (e.g., ground) 242 through contacts 226, which are coupled to Vss contacts of the interposer through TSVs. These interposer Vss contacts are coupled to substrate Vss contacts through conductive lines 237. Similarly, the active transceiver blocks, 210A and 211C are coupled to off-package connections through chip contacts 227, interposer TSVs, interposer contacts (“IO”), and substrate IO lines 236, as shown. Note that with this embodiment, the interior, inactive transceiver blocks are coupled to ground in order to minimize parasitics and power losses, but any suitable alternative connections or even non-connections could be used. That is, they could be left open, or even coupled to other or multiple different reference or device planes depending on design objectives.

The signal lines 244 couple the adjacent D2D block pairs (217A-219B and 217B-219C) to one another for chip-to-chip communications. The reference layer 242, from a top view perspective (not shown) may have gaps or openings to accommodate the signal lines and possibly other signals (e.g., IO from active transceivers). Alternatively, the signal lines could be formed from vias or micro vias with insulating lateral surfaces.

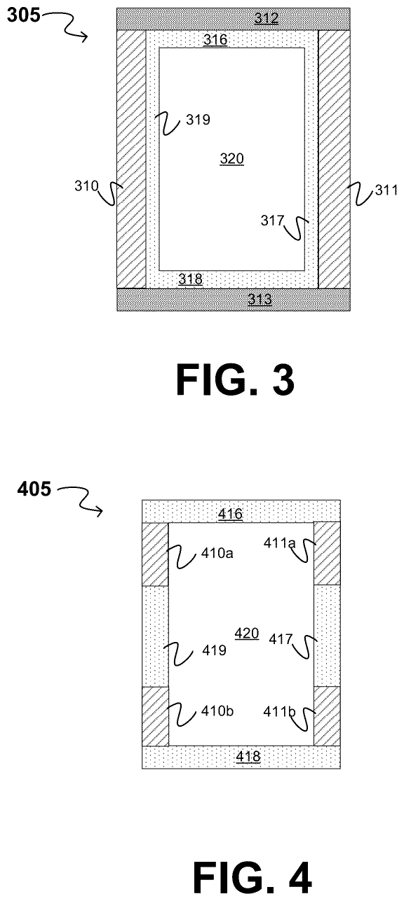

FIG. 3 shows another programmable device die 305 that may be used for generating multi-chip systems with a single die design in accordance with some embodiments. This die comprises a peripheral (or shoreline) region that is composed of an inner peripheral portion and an outer peripheral portion. The inner peripheral portion is made up of general IO (e.g., D2D) blocks 316-319, while the outer peripheral portion is made up of transceiver blocks 310, 311, and off-chip IO blocks (e.g., DDR, USB) 312, 313. With such a design, dies may be coupled together from any of their four sides. This may be convenient for systems with large numbers of dies, allowing for arrays with multiple rows and multiple columns of dies to be configured within a multi-chip package.

FIG. 4 shows yet another device, die 405 that may be used for generating multi-chip systems with a single die design in accordance with some embodiments. Die (e.g., FPGA) 400 comprises a peripheral region that includes both D2D blocks 416-419 and transceiver blocks 410a,b and 411a,b, as shown. Rather than simply using inner and outer peripheral portions, the transceiver and D2D blocks are interleaved around the peripheral region. In this way, adjacent D2D blocks from side-by-side dies may be coupled together, simplifying, in some cases, the utilized package methodologies.

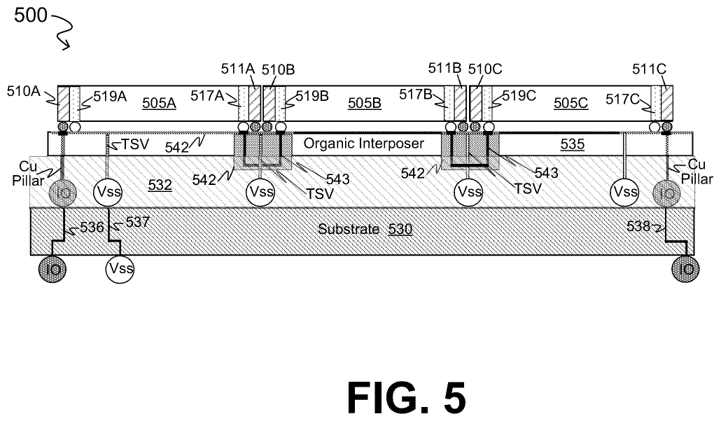

FIG. 5 is a side view showing another multi-chip system 500 in accordance with some embodiments. System 500 includes die instances 505A, 505B, and 505C mounted organic interposer 535, which is mounted atop a mid substrate portion 532, which may be a part of substrate 530. The mid substrate 532 and organic interposer 535 house bridge structures 542, which include bridge conductors 543 for coupling adjacent D2D blocks (517A-519B and 517B-519C) together. The package also includes TSVs passing through the bridges to couple inactive transceiver blocks to inactive device reference planes (Vss). Also included are copper pillars and TSVs for coupling, through the organic interposer and substrate portions, transceiver blocks (510A, 511C) to IO contacts and inactive IO blocks (D2D portions (519A, 517C) to Vss reference planes. In some embodiments, the organic interposer could be omitted, with bridge structures disposed directly within the mid substrate portion. In addition, the mid substrate portion may be formed as a separate layer from the substrate, or it could be part of the substrate itself.

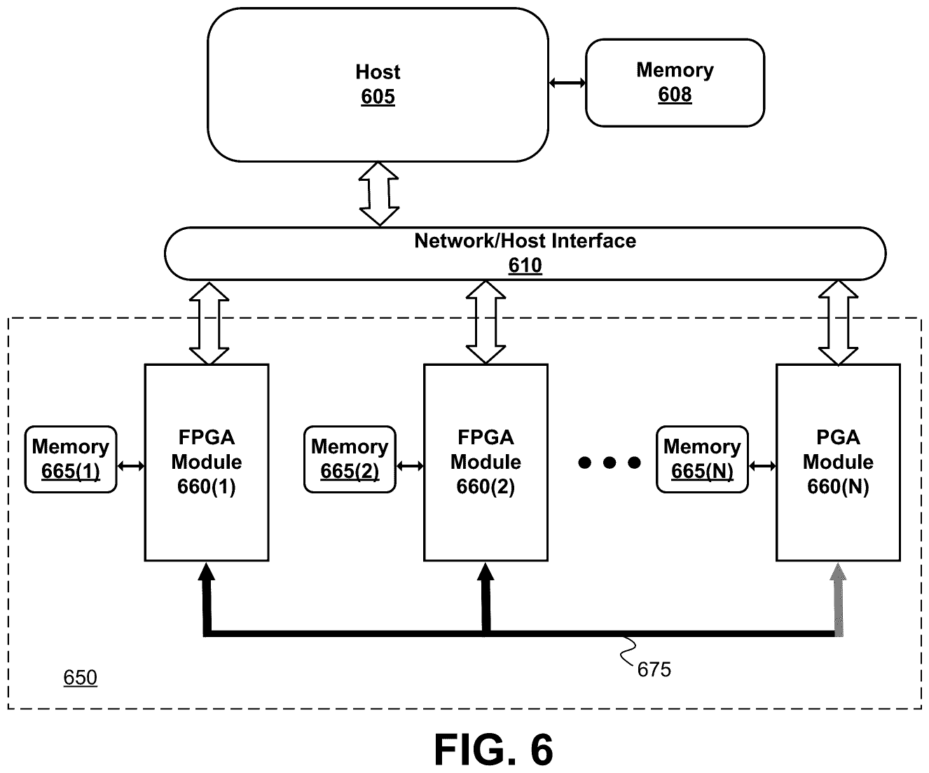

FIG. 6 shows an exemplary compute system 650 formed from one or more FPGA modules 660, each having one or more dies of a single design instantiation, as described herein. (They may also include other components such as power supplies, ASICS or even other FPGA designs.) Each FPGA module 660 also has an associated external memory module 665. The FPGA modules 660 are coupled to each other through a communications bridge 675. Also illustrated is a host processor 605 having associated memory 608. The host processor is coupled to the compute system 650 through a host interface bridge 610 for controlling and communicating with FPGA system 650. Host 605, in cooperation with memory 608, may be used to program the one or more FPGA modules 660, as well as to control and program the system for such tasks as compute system prototyping, as well as for other possible functions.

Compute system prototyping may be a highly beneficial use of FPGA modules 660 in accordance with some embodiments. Hardware platforms such as FPGA prototyping are growing in popularity due to their relative low expense and ability to test system designs at speed versus simulation which is too slow and often can't provide an accurate assessment of design behavior. FPGA-based prototyping may be well suited for even the largest designs. An FPGA based prototype system allows engineers to use the same software in the prototype system as with the final product, thus allowing an early start in software development. The architecture for the prototype need only include minor additions compared to the final architecture. Therefore, the evaluation of different configurations and functionality verification may be simple, reliable, and fast. It also allows for the evaluation of large system-on-chips using one or more multi-FPGA modules such as a multi-FPGA module 200, 500, and/or 660, as previously discussed. When combined with the ability to control the clocking of individual components, such a configuration allows analysis of both software and hardware. Another benefit is that FPGA-based compute system prototypes can use synthesizable RTL (register transfer language) developed for an actual hardened design to provide cycle-accurate, high-performance execution and real-world interface connectivity. This performance can scale with the complexity of designs thanks to the flexibility of prototyping solutions that allow design partitioning across multiple FPGAs to be utilized in order to handle very large design sizes requiring massive verification throughput. This also brings the added benefit of more time to perform exhaustive verification of large designs, or to allow additional exploration of design options. While verification may be a primary use, physical prototyping supports other use cases, including proof-of-concept research, test pattern generation, IP development, end-user evaluation, and even as highly configurable computer systems for varieties of applications.

It should be appreciated that the FPGA modules 660 may be a component included in any suitable data processing system, such as a data processing system 600, shown in FIG. 6. The data processing system 600 may include the FPGA system 650. The data processing system 600 may include more or fewer components (e.g., electronic display, user interface structures, application specific integrated circuits (ASICs)). Moreover, any of the circuit components depicted in FIG. 6 may include an FPGA module as discussed herein (e.g., 200, 500, 660). The host processor 605 may include any of the foregoing processors that may manage a data processing request for the data processing system 600 (e.g., to perform encryption, decryption, machine learning, video processing, voice recognition, image recognition, data compression, database search ranking, bioinformatics, network security pattern identification, spatial navigation, cryptocurrency operations, hardware prototyping, or the like). The memory 608, 665 may include random access memory (RAM), read-only memory (ROM), one or more hard drives, flash memory, or the like. The memory and/or storage circuitry may hold data to be processed by the data processing system 600. In some cases, the memory and/or storage circuitry may also store configuration programs (bitstreams) for programming the FPGA modules 660. The host interface 610 may allow the data processing system 600 to communicate with other electronic devices. The data processing system 600 may include several different packages or may be contained within a single package on a single package substrate. For example, components of the data processing system 600 may be located on several different packages at one location (e.g., a data center) or multiple locations. For instance, components of the data processing system 600 may be located in separate geographic locations or areas, such as cities, states, or countries.

In some embodiments, the data processing system 600 may be part of a data center that processes a variety of different requests. For instance, the data processing system 600 may receive a data processing request via the host/network interface 610 to perform encryption, decryption, machine learning, video processing, voice recognition, image recognition, data compression, database search ranking, bioinformatics, network security pattern identification, spatial navigation, digital signal processing, or some other specialized task.

Illustrative examples of the technologies disclosed herein are provided below. An embodiment of the technologies may include any one or more, and any compatible combination of, the examples described below.

Example 1 is a multi-chip module that includes first and second dies that each have a first side including a peripheral region with both transceiver and D2D blocks and a second side that includes a peripheral region with both transceiver and D2D blocks. The first die is disposed next to the second die such that the second side of the first die is next to the first side of the second die, and at least a portion of the D2D block of the first die's second side is coupled to at least a portion of the D2D block of the second die's first side. Moreover, at least some of the D2D blocks are unused when in a side that does not have a neighboring die, and wherein some of the transceiver blocks are unused when in a side of the die that does have a neighboring die. It should be appreciated that any suitable die type, e.g., PLD, FPGA, CPU, GPU, ASIC, and the like could be used for implementing these dies, in this, and in the other examples presented throughout the specification.

Example 2 includes the subject matter of example 1, and wherein the coupled together general IO blocks from the first and second dies include die-to-die IO interfaces for communicatively coupling the first die to the second die.

Example 3 includes the subject matter of any of examples 1-2, and wherein the first and second dies are field programmable gate array dies.

Example 4 includes the subject matter of any of examples 1-3, and wherein the first and second dies are separate instances of the same die design.

Example 5 includes the subject matter of any of examples 1-4, and wherein the general IO blocks are disposed between the transceiver blocks.

Example 6 includes the subject matter of any of examples 1-5, and wherein the transceiver and general IO blocks in each peripheral region are interleaved, whereby each block is at an outer edge of its die.

Example 7 includes the subject matter of any of examples 1-6, and wherein the first and second dies are mounted on an interposer having signal lines for coupling general IO block portions from the first die's second side to the second die's first side.

Example 8 includes the subject matter of any of examples 1-7, and wherein the interposer has a reference plane coupled to the transceiver s on the first die's second side and second die's first side to render them inert.

Example 9 includes the subject matter of any of examples 1-8, and wherein the first and second dies are mounted atop an organic substrate portion that includes at least one bridge for coupling general IO block portions from the first die's second side to the second die's first side.

Example 10 is an apparatus that includes a programable integrated circuit die. The die has an interior processing region and a peripheral region that includes an inner general IO block and an outer transceiver block. The inner general IO block is disposed between the outer transceiver block and the interior processing region.

Example 11 includes the subject matter of example 10, and wherein the general IO block includes D2D circuitry.

Example 12 includes the subject matter of any of examples 10-11, and wherein the D2D circuitry comprises SerDes circuits.

Example 13 includes the subject matter of any of examples 10-12, and wherein the peripheral region occupies opposite sides of the die.

Example 14 includes the subject matter of any of examples 10-13, and further comprising a second die that is a separate instance of the programmable integrated circuit die, which is a first die.

Example 15 includes the subject matter of any of examples 10-14, and wherein the first and second dies are mounted on an interposer having signal lines for coupling general IO block portions from the first die to the second die.

Example 16 includes the subject matter of any of examples 10-15, and wherein the interposer has a reference plane coupled to the transceiver blocks that are to be inert from the first and second dies.

Example 17 includes the subject matter of any of examples 10-16, and wherein the first and second dies are mounted atop an organic substrate portion that includes at least one bridge for coupling general IO block portions from the first and second dies to one another.

Example 18 is an apparatus that includes a substrate and a substrate; and first and second FPGA dies. The first and second FPGA dies are of the same design and are mounted to the substrate. The first and second dies have adjacent sides that each include (i) a D2D block within a peripheral region, and (ii) an unused transceiver block within the peripheral region. The D2D blocks are coupled to one another, and the transceiver blocks are coupled to a reference rail to render them inert.

Example 19 includes the subject matter of example 18, and wherein the first and second dies are mounted to the substrate through an organic material.

Example 20 includes the subject matter of any of examples 18-19, and wherein the D2D blocks are coupled together through at least one bridge having multiple signal lines.

Example 21 includes the subject matter of any of examples 18-20, and further comprising through silicon vias (TSVs) passing through the at least one bridges to couple the unused transceiver blocks to the reference rail.

Example 22 includes the subject matter of any of examples 18-21, and wherein the reference rail is a ground plane.

Example 23 includes the subject matter of any of examples 18-22, and wherein the first and second dies are mounted to an interposer.

Example 24 includes the subject matter of any of examples 18-23, and wherein the interposer is a silicon interposer.

Example 25 is a data processing apparatus including at least one FPGA module having the first and second dies in accordance with the examples of examples 18-24.

Example 26 is programmable device module that includes a substrate and first and second FPGA dies. The first and second FPGA dies are of the same design and are mounted to the substrate. Moreover, the first and second dies have adjacent sides that each include (i) a D2D block within a peripheral region, and (ii) an unused transceiver block within the peripheral region. The module also includes means for coupling the D2D blocks to one another.

Example 27 includes the subject matter of example 26, and wherein the transceiver blocks are coupled to a reference rail to render them inert.

Example 28 includes the subject matter of any of examples 26-27, and wherein the first and second dies are mounted to the substrate through an organic layer.

Example 29 includes the subject matter of any of examples 26-28, and the coupling means comprises at least one bridge.

Example 30 includes the subject matter of any of examples 26-29, and wherein the coupling means comprises through silicon vias (TSVs) passing through the at least one bridges to couple the unused transceiver blocks to a reference rail.

Example 31 includes the subject matter of any of examples 26-30, and wherein the reference rail is a ground plane.

Example 32 includes the subject matter of any of examples 26-31, and wherein the first and second dies are mounted to an interposer.

Example 33 includes the subject matter of any of examples 26-32, and wherein the interposer is a silicon interposer.

Example 34 is a computing system with at least one module having the subject matter of any of examples 26-33.

Example 35 includes the subject matter of example 34 and further comprising at least one FPGA module to prototype a hardware system.

Example 36 is a multi-chip module that includes identical first and second dies having a peripheral region containing die to die IO on at least two sides of the die. At least some of the die-to-die IO in the package are unused when that side of the die does not have a neighboring die and some of the off package IO are unused when that side of the die does have a neighboring die.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. Different circuits or modules may share or even consist of common components. for example, A controller circuit may be a circuit to perform a first function and at the same time, the same controller circuit may also be a circuit to perform another function, related or not related to the first function.

The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are dependent upon the platform within which the present disclosure is to be implemented.

What is claimed is:

1. A multi-chip module, comprising:
first and second dies each having a first side including a peripheral region with both transceiver and D2D blocks and a second side that includes a peripheral region with both transceiver and D2D blocks;
wherein the first die is disposed next to the second die such that the second side of the first die is next to the first side of the second die, at least a portion of the D2D block of the first die's second side being coupled to at least a portion of the D2D block of the second die's first side; and
wherein at least some of the D2D blocks are unused when in a side that does not have a neighboring die, and wherein some of the transceiver blocks are unused when in a side of the die that does have a neighboring die.

2. The module of claim 1, wherein the first and second dies are field programmable gate array dies.

3. The module of claim 1, wherein the first and second dies are separate instances of the same die design.

4. The module of claim 1, wherein the general IO blocks are disposed between the transceiver blocks.

5. The module of claim 1, wherein the transceiver and general IO blocks in each peripheral region are interleaved, whereby each block is at an outer edge of its die.

6. The module of claim 1, wherein the first and second dies are mounted on an interposer having signal lines for coupling general IO block portions from the first die's second side to the second die's first side.

7. The module of claim 6, wherein the interposer has a reference plane coupled to the transceiver s on the first die's second side and second die's first side to render them inert.

8. The module of claim 1, wherein the first and second dies are mounted atop an organic substrate portion that includes at least one bridge for coupling general IO block portions from the first die's second side to the second die's first side.

9. A programable integrated circuit die apparatus, comprising:
an interior processing region; and
a peripheral region including an inner general IO block and an outer transceiver block, the inner general IO block being disposed between the outer transceiver block and interior processing region.

10. The apparatus of claim 9, wherein the general IO block includes D2D circuitry.

11. The apparatus of claim 10, wherein the D2D circuitry comprises Serdes circuits.

12. The apparatus of claim 9, wherein the peripheral region occupies opposite sides of the die

13. The apparatus of claim 9, further comprising a second die that is a separate instance of the programmable integrated circuit die, which is a first die.

14. The apparatus of claim 13, wherein the first and second dies are mounted on an interposer having signal lines for coupling general IO block portions from the first die to the second die.

15. The apparatus of claim 14, wherein the interposer has a reference plane coupled to the transceiver blocks that are to be inert from the first and second dies

16. The apparatus of claim 13, wherein the first and second dies are mounted atop an organic substrate portion that includes at least one bridge for coupling general IO block portions from the first and second dies to one another.

17. An apparatus, comprising:
a substrate; and
first and second FPGA dies of the same design mounted to the substrate, the first and second dies having adjacent sides each including (i) a D2D block within a peripheral region, and (ii) an unused transceiver block within the peripheral region, wherein the D2D blocks are coupled to one another and the transceiver blocks are coupled to a reference rail to render them inert.

18. The apparatus of claim 17, wherein the first and second dies are mounted to the substrate through an organic material.

19. The apparatus of claim 18, wherein the D2D blocks are coupled together through at least one bridge having multiple signal lines.

20. The apparatus of claim 19, comprising through silicon vias (TSVs) passing through the at least one bridges to couple the unused transceiver blocks to the reference rail.

21. The apparatus of claim 20, wherein the reference rail is a ground plane.

22. The apparatus of claim 17, wherein the first and second dies are mounted to an interposer.

23. The apparatus of claim 22, wherein the interposer is a silicon interposer.

24. A data processing apparatus comprising at least one FPGA module having the first and second dies in accordance with the apparatus of claim 17.
